(19) United States
(12) Patent Application Publication
(10) Pub. No.: US 2020/0095115 A1
(43) Pub. Date: Mar. 26, 2020

(54) SEMICONDUCTOR DEVICE AND METHOD FOR MANUFACTURING THE SAME

(71) Applicant: DENSO CORPORATION, Kariya-city (JP)

(72) Inventors: Takahiro KAWANO, Kariya-city (JP); Hisanori YOKURA, Kariya-city (JP); Tsuyoshi FUJIWARA, Kariya-city (JP)

(21) Appl. No.: 16/697,517

(22) Filed: Nov. 27, 2019

Related U.S. Application Data
(63) Continuation of application No. PCT/JP2018/018297, filed on May 11, 2018.

(30) Foreign Application Priority Data
Jun. 13, 2017 (JP) 2017-116207

(51) Int. Cl. B81B 3/00; B81C 1/00; G01L 9/00

(52) U.S. Cl. CPC B81B 3/0086; B81C 1/00698; G01L 9/0051; G01L 2009/0066; B81B 2203/0127; B81B 2203/0315; B81C 2203/036; B81B 2201/0264

(57) ABSTRACT

A semiconductor device includes a first substrate having a first surface, and a second substrate having a second surface. A part of the second substrate is bonded to a part of the first surface with atmospheric pressure plasma. The semiconductor device further includes an oxide film disposed on the first surface of the first substrate, and a protection film layered on a surface of the oxide film opposite to the first substrate.

### CROSS REFERENCE TO RELATED APPLICATIONS

The present application is a continuation application of International Patent Application No. PCT/JP2018/018297 filed on May 11, 2018, which designated the U.S. and claims the benefit of priority from Japanese Patent Application No. 2017-116207 filed on Jun. 13, 2017. The entire disclosures of all of the above applications are incorporated herein by reference.

### TECHNICAL FIELD

The present disclosure relates to a semiconductor device with plasma-bonding and a method for manufacturing the same.

### BACKGROUND

For example, it is known to form a semiconductor device by bonding two silicon wafers. In the bonding of the silicon wafers, the silicon wafers are placed to be in contact with each other, and then are subjected to a heat treatment so as to be bonded with each other.

### SUMMARY

The present disclosure describes a semiconductor device including a first substrate having a first surface and a second substrate having a second surface. A part of the first surface of the first substrate is bonded to a part of the second surface of the second substrate by means of an atmospheric pressure plasma activation.

### BRIEF DESCRIPTION OF DRAWINGS

Features and advantages of the present disclosure will become more apparent from the following detailed description made with reference to the accompanying drawings, in which:

FIG. 1 is a diagram illustrating a cross-sectional view for showing a configuration of a semiconductor device according to the first embodiment;

FIG. 2 is a diagram illustrating a cross-sectional view for showing a step of forming a first substrate and a step of forming an impurity region;

FIG. 3 is a diagram illustrating a cross-sectional view for showing a step of forming an oxide film;

FIG. 4 is a diagram illustrating a cross-sectional view for showing a step of forming a protection film;

FIG. 5 is a diagram illustrating a cross-sectional view for showing a step of activation with atmospheric pressure plasma;

FIG. 6 is a diagram illustrating a cross-sectional view for showing a step of bonding the first substrate and a second substrate;

FIG. 7 is a diagram illustrating a cross-sectional view for showing a step of forming a diaphragm; and

FIG. 8 is a diagram illustrating a cross-sectional view for showing a configuration of a semiconductor device according to a second embodiment.

### DETAILED DESCRIPTION

When silicon wafers are bonded in order to form a semiconductor device, the silicon wafers are placed to be in contact with each other, and then are subjected to a heat treatment. In this case, however, the temperature of the heat treatment needs to be approximately 1200° C. (degrees Celsius). Therefore, there is a possibility that impurity ions and the like constituting an impurity region, which has been separately formed, will be unnecessarily thermally diffused. In particular, if an out-diffusion where ions are diffused to a space outside of the wafers occurs, impurities are likely to accumulate on the surface of the wafers again. It may cause unintentional electric characteristics.

Thus, it is conceivable to use an atmospheric pressure plasma technique for activation. When a bonding surface of the silicon wafer, which is to be bonded to another silicon wafer, is irradiated with atmospheric pressure plasma, OH-groups are activated on the surface. Thus, it is possible to relatively increase a bonding strength. Even in such a case, however, the heat treatment for the bonding is necessary and thus the out-diffusion may still occur. Therefore, it is considered to form an oxide film on the surface of the wafer in which wirings and an impurity region are formed, in order to physically suppress diffusion of the impurities to outside.

In order to reduce the number of manufacturing steps, the oxide film for suppressing the out-diffusion may be provided by an oxide film that is used as a mask, for example, during ion implantation and remained without being removed. Alternatively, the oxide film for suppressing the out-diffusion may be provided by an oxide film that is newly formed, after the ion implantation, for insulation of the wirings. In such cases, the oxide film generally has a thickness in a range from 10 nm to 1000 nm.

The inventors of the present disclosure have found that, if the atmospheric pressure plasma treatment is performed in a condition where the oxide film having such a thickness is kept, the oxide film is electrified and the oxide film and the silicon wafer underneath the oxide film thus have scars due to shock of discharging.

According to a first aspect of the present disclosure, a semiconductor device includes a first substrate, a second substrate, an oxide film and a protection film. The first substrate has a first surface. The second substrate has a second surface, and a part of the second surface is bonded to a part of the first surface by means of atmospheric pressure plasma activation. The oxide film is disposed on the first surface of the first substrate. The protection film is disposed on a surface of the oxide film opposite to the first substrate.

According to a second aspect of the present disclosure, a method for manufacturing a semiconductor device, which includes a first substrate having a first surface, and a second substrate having a second surface a part of which is bonded to a part of the first surface by means of atmospheric pressure plasma activation, includes: preparing a first substrate; forming an oxide film on the first surface; forming an impurity region in the first substrate; forming, after the forming of the oxide film and the forming of the impurity region, a protection film on a surface of the oxide film opposite to the first substrate; performing, after the forming of the protection film, a plasma activation treatment at an atmospheric pressure to the first surface; joining, after the plasma activation treatment, the first surface of the first substrate and the second surface of the second substrate; and performing a heat treatment, after the joining of the first surface and the second surface, to the first substrate and the second substrate so as to bond the part of the first surface and the part of the second surface to each other.

In the above configuration, since the protection film is layered in addition to the oxide film, a total thickness of films layered on the first surface can be increased. The increase in thickness enhances withstand voltage. As a result, an occurrence of discharging, which causes breakdown, during the surface treatment by means of the atmospheric pressure plasma will be suppressed. As such, the occurrence of scars in the oxide film and the substrate underneath the oxide film will be suppressed.

Embodiments of the present disclosure will be described in detail with reference to the drawings. In each embodiment, sections corresponding to items described in the preceding embodiment are denoted by the same reference numerals, and their repetitive description might be omitted. In each embodiment, in the case where only a part of a configuration is described, the precedingly described embodiment can be applied to the other part of the configuration. It is possible not only to combine parts that can be explicitly combined in the embodiments, but also to partially combine the embodiments even if not explicitly specified if there is no trouble with the combination.

### First Embodiment

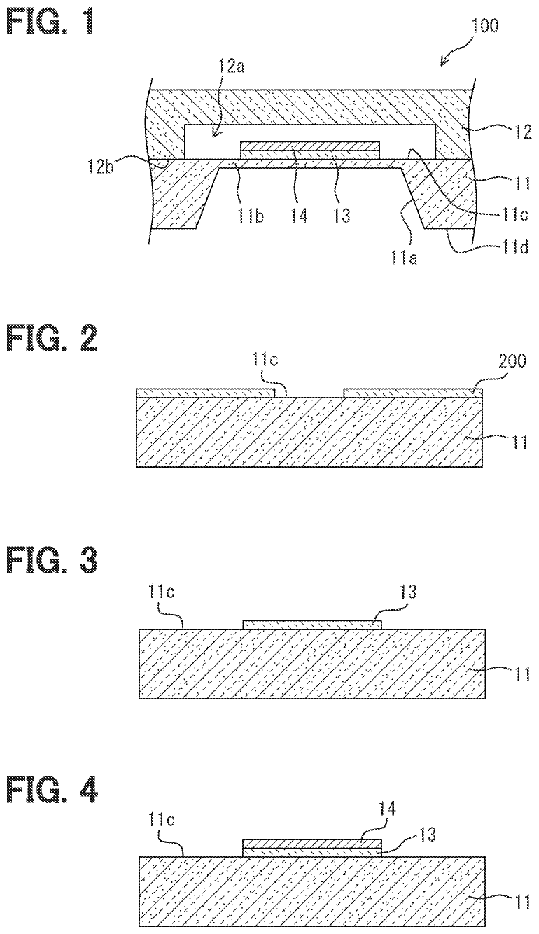

A schematic configuration of a semiconductor device according to the present embodiment will be described with reference to FIG. 1.

A semiconductor device 100 is a pressure sensor of a diaphragm-type, for example. The diaphragm-type pressure sensor is provided with a plurality of resistance elements. The semiconductor substrate is formed with a diaphragm, and the resistance elements are formed on the diaphragm so as to constitute a bridge circuit. The resistance values of the resistance elements vary in accordance with deformation of the diaphragm caused by a change in pressure, resulting in a change in output of the bridge circuit. In this way, pressure is detected.

The pressure sensor in such a mode has a cavity for maintaining a reference pressure. The cavity is provided by a space defined between two semiconductor substrates bonded to each other. The bonding of the semiconductor substrates is realized by a plasma bonding, in particular, a plasma bonding using atmospheric pressure plasma.

As shown in FIG. 1, the semiconductor device 100 includes a first substrate 11, a second substrate 12, an oxide film 13 and a protection film 14.

The first substrate 11 is a semiconductor substrate mainly made of silicon. The first substrate 11 has a planar plate shape including a main surface 11c and a back surface 11d. The first substrate 11 is formed with a recessed portion 11a that is recessed from the back surface 11d by etching or the like. A thickness of the first substrate 11 where the recessed portion 11a is formed, that is, a thickness between a bottom surface of the recessed portion 11a and the main surface 11c is thus smaller than a thickness where the recessed portion 11a is not formed. A diaphragm 11b is thus provided by the thin region where the recessed portion 11a is formed. The diaphragm 11b is formed with an impurity region (not shown), which is formed by ion implantation, and wirings. The impurity region forms the resistance elements and diodes, and the wirings contribute to electric connections of the bridge circuit or other external devices. In other words, the first substrate 11 has the impurity region adjacent to the main surface 11c, and a sensor element constituting a part of the pressure sensor is formed in the impurity region. The main surface 11c corresponds to a first surface of the first substrate 11.

The second substrate 12 is a semiconductor substrate mainly made of silicon. The second substrate 12 has a planar plate shape including a main surface 12b. The second substrate 12 is formed with a recessed portion 12a that is recessed from the main surface 12b by etching or the like. The recessed portion 12a has a size that can entirely encompass the diaphragm 11b of the first substrate 11. The recessed portion 12a has a depth that can accommodate the oxide film 13 and the protection film 14, which will be described later, therein. The main surface 12b of the second substrate 12 corresponds to a second surface of the second substrate 12.

The first substrate 11 and the second substrate 12 are bonded to each other such that the first surface 11c and the second surface 12b are opposed to each other. When the first and second substrates 11 and 12 are viewed orthogonal to the main surfaces 11c and 12b, the second substrate 12 is configured that the recessed portion 12a formed on the main surface 12b encompass the entirety of the diaphragm 11b. That is, when the first substrate 11 and the second substrate 12 are bonded to each other, a space is defined on a side opposite to the recessed portion 11a with respect to the diaphragm 11b. This space is isolated from the outside, and serves as a cavity for maintaining a reference pressure.

The main surface 11c (the first surface) of the first substrate 11 and the main surface 12b (the second surface) of the second substrate 12 are plasma-bonded with each other. In particular, in the present embodiment, the main surface 11c is subjected to an activation treatment using atmospheric pressure plasma, and is bonded to the main surface 12b. Therefore, OH-groups are activated on the main surface 11c before the bonding, and a bonding strength between the main surfaces 11c and 12b after the bonding is increased, as compared with a case of a vacuum plasma treatment.

The oxide film 13 is a silicon oxide film formed on the main surface 11c, and on the diaphragm 11b. The oxide film 13 is layered so as to cover the impurity region formed in the diaphragm 11b. The oxide film 13 has a function of restricting scattering of impurity ions of the impurity region, which are transpired when the first substrate 11 is heated, to the outside of the first substrate 11.

The oxide film 13 is provided by a part of an oxide film that is formed for the purpose of mask or electrical insulation in ion implantation or in a step associated with forming of wirings, and remained without being removed. In general, such an oxide film has a thickness in a range from 10 nm to 1000 nm. In the present embodiment, the oxide film 13 has the thickness of 100 nm, for example.

The protection film 14 is layered on the oxide film 13. In the present embodiment, the protection film 14 is provided as an insulation film. In particular, the protection film 14 is mainly made of silicon nitride. The protection film 14 is formed to cover the entirety of a surface of the oxide film 13, the surface being opposite to a surface of the oxide film 13 being in contact with the diaphragm 11b. The protection film 14 has a thickness of 50 nm, for example.

The diaphragm 11b is entirely covered in the cavity, and the oxide film 13 and the protection film 14 disposed on the diaphragm 11b are thus necessarily accommodated in the cavity. The recessed portion 12a formed in the second substrate 12 has the depth that allows the oxide film 13 and the protection film 14 to be accommodated in the cavity. Further, there is a clearance between the bottom surface of the recessed portion 12a forming the cavity and the protection film 14.

Next, a method for manufacturing a semiconductor device 100 according to the present embodiment will be described with reference to FIGS. 2 to 7.

Firstly, as shown in FIG. 2, a first substrate 11 is prepared, and an oxide film 200 is formed on a main surface 11c of the first substrate 11. The oxide film 200 is film-formed by a general technique such as by thermal oxidation or CVD. After the oxide film 200 is formed on the entirety of the main surface 11c, a mask resist is film-formed and etching is performed. When the mask resist is removed, the oxide film 200 that is patterned as shown in FIG. 2 is formed.

Next, an ion implantation is conducted to the main surface 11c of the first substrate 11. Thus, an impurity region is formed in a surface layer of the main surface 11c, and resistance elements and diodes are formed. Further, wirings and pads are formed. Thereafter, unnecessary oxide film 200 is removed.

Next, as shown in FIG. 3, an oxide film 13 is formed. For example, the oxide film 13 is formed in the same step as forming an insulation film that is performed for the purpose of insulation of the wirings. Alternatively, the oxide film 13 may be formed in an independent step separated from the forming of the insulation film that is performed for the purpose of insulation of the wirings.

The oxide film 13 is formed so as to cover an element formation region where the resistance elements and diodes are formed with the formation of the impurity region. The oxide film 13 serves as an anti-out diffusion film that restricts scattering of ions from the impurity region in a subsequent separate step associated with heating.

The oxide film 13 of the present embodiment is formed simultaneously with the insulation film that is formed for the purpose of electric insulation of the wirings and the like. Therefore, the thickness of the oxide film 13 is set so as to sufficiently enable insulation of the wirings and the like. For example, the thickness of the oxide film 13 is approximately 100 nm. The thickness depends on conditions for forming another semiconductor element formed in the surface layer of the main surface 11c, and can be different in a range from approximately 10 nm to approximately 1000 nm.

Next, as shown in FIG. 4, a protection film 14 is formed. As described above, the protection film 14 of the present embodiment is mainly made of silicon nitride. The protection film 14 is layered on the oxide film 13 by a CVD technique. As examples of the CVD technique, a plasma enhanced chemical vapor deposition (PECVD) or a reduced pressure chemical vapor deposition (LPCVD) may be used. Alternatively, the protection film 14 may be layered by sputtering. The thickness of the protection film 14 of the present embodiment is approximately 50 nm, for example.

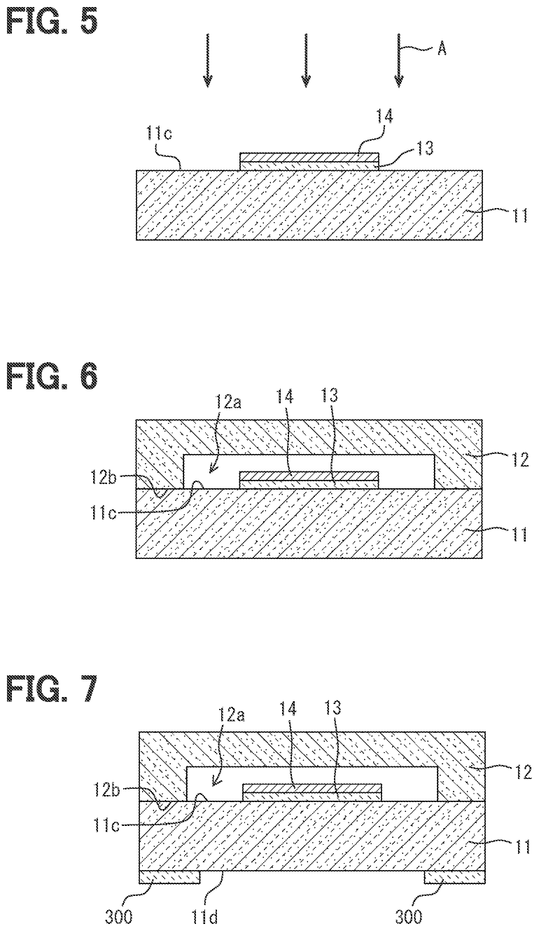

Next, a plasma activation treatment is performed. The first substrate 11 on which the oxide film 13 and the protection film 14 have been layered is placed at an atmospheric pressure. As shown by arrows A in FIG. 5, atmospheric pressure plasma is applied to the main surface 11c. The atmospheric pressure plasma is applied so as to activate at least the bonding surface to be bonded with the second substrate 12. When the atmospheric pressure plasma is applied, hydroxyl groups (OH-groups) are activated on the main surface 11c.

Next, as shown in FIG. 6, a second substrate 12 is prepared, and bonded to the first substrate 11. The second substrate 12 is formed with the recessed portion 12a in the main surface 12b in advance. The recessed portion 12a is, for example, formed by etching.

In bonding the second substrate 12 and the first substrate 11, the second substrate 12 is placed relative to the first substrate 11 so that the main surface 12b faces the main surface 11c of the first substrate 11, and the main surface 12b of the second substrate 12 is brought into contact with the main surface 11c of the first substrate 11. Further, the first substrate 11 and the second substrate 12 are heated at a temperature in a range from approximately 200° C. to approximately 800° C. As a result, the two main surfaces 11c and 12b are closely in contact with each other and fixed to each other. Since the main surface 11c of the first substrate 11 has been treated with the atmospheric pressure plasma to activate the OH-groups, the bonding strength is higher than that by a plasma bonding under vacuum condition.

Next, as shown in FIG. 7, a patterned oxide film 300 is formed in a region on the back surface 11d of the first substrate 11, the region excluding a region where the recessed portion 11a is to be formed. Then, the recessed portion 11a is formed by etching, and the diaphragm 11b is eventually formed.

Through the steps described above, the semiconductor device 100 as the pressure sensor can be manufactured.

Next, advantageous effects achieved by the semiconductor device 100 of the present embodiment and the method for manufacturing the semiconductor device 100 will be described.

The semiconductor device 100 has the oxide film 13 on the main surface 11c of the first substrate 11 including the impurity region and in which a circuit is formed. Therefore, in the step of heating for bonding the first substrate 11 and the second substrate 12, scattering of components, such as ions forming the impurity region, from the main surface 11c can be suppressed. That is, the out-diffusion can be restricted.

In the semiconductor device 100, the protection film 14 is layered, in addition to the oxide film 13. Therefore, the total thickness of the films formed on the first surface (main surface 11c) can be increased. The increase in thickness enhances withstand voltage. As a result, an occurrence of discharge, which causes breakdown, can be suppressed during the surface treatment with the atmospheric pressure plasma. Accordingly, an occurrence of scars in the oxide film 13 and the base underneath the oxide film 13 can be suppressed.

The thickness of the protection film 14 is preferably set so that the total thickness of the protection film 14 and the oxide film 13 allows the withstand voltage over the electric charge amount of the first substrate 11. The thickness of the protection film 14 layered is in a range from 10 nm to 100 nm. The protection film 14 of the present embodiment is mainly made of silicon nitride. Thus, an electrical effect moderation effect due to an ONO structure with the oxide film 13 that is silicon oxide film is generated. For this reason, the protection film 14 can be further reduced in thickness. The inventors of the present disclosure have confirmed through experiment that, even if the thickness of the protection film 14 is in a range from 4 nm to 10 nm, an occurrence of scars caused by atmospheric pressure plasma can be suppressed.

That is, in the case where the protection film 14 is provided by a silicon nitride film, the thickness of the protection film 14 is further reduced. Therefore, deformation of the diaphragm 11b, for example, cause by a difference between a linear thermal expansion coefficient of the oxide film 13 and a linear thermal expansion coefficient of the protection film 14 can be suppressed. As such, a degradation of pressure detection sensitivity caused by the formation of the protection film 14 can be suppressed.

### Modification

In the embodiment described hereinabove, the insulation film used as the protection film 14 is exemplarily made of silicon nitride. However, the protection film 14 is not limited to the silicon nitride film as long as the protection film 14 and the oxide film 13 are formed to have the total thickness that allows withstand voltage over the electric charge amount of the first substrate 11. That is, as the protection film 14, thermal oxidation SiO₂ film, BPSG film, TEOS film and SIO₂ film by the CVD may be used.

The protection film 14 is not limited to the insulation film, but may be an electrically conductive film. For example, as the protection film 14, polysilicon may be used, or metal may be used. For a metal film, for example, aluminum, titanium, titanium nitride, copper, tungsten may be used. In particular, polysilicon can be easily formed on the oxide layer 13 by CVD technique or the like, and is thus suitable.

In a case where the protection film 14 is made of an electrically conductive film, during the activation treatment by the atmospheric pressure plasma, charges are smoothly exchanged between the oxide film 13 and protection film 14 and the flow of plasma. Therefore, the electric charge amount of the oxide film 13 and the protection film 14 can be reduced. The exchange of the electric charges with the flow of plasma is mainly conducted by the protection film 14, which is the electrically conductive film. Therefore, the advantageous effects as described above can be achieved as long as the electrically conductive film is present on the oxide film 13 at least. That is, the thickness of the protection film 14 in this case may be in a range from approximately 1 nm to approximately 10 nm.

### Second Embodiment

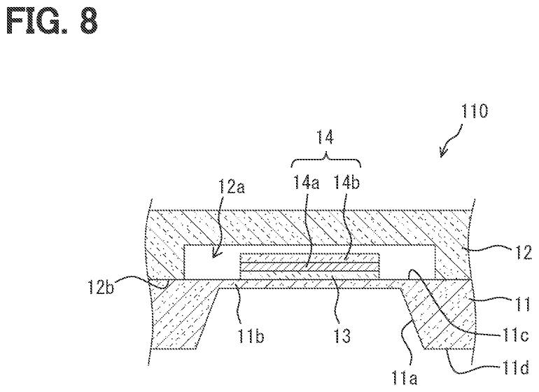

In the first embodiment and the modification of the first embodiment, the protection film 14 is provided by a single layered film made of one component as a main component. In a semiconductor device 110 of the present embodiment, on the other hand, a protection film 14 has a multilayer structure including a first layer 14a and a second layer 14b, as shown in FIG. 8. Configurations of the semiconductor device 110 other than the protection film 14 are similar to those of the semiconductor device 100 of the first embodiment.

In the protection film 14 of the present embodiment, the first layer 14a is a silicon nitride film, and is similar to the protection film 14 of the first embodiment. The second layer 14b is a silicon oxide film. As described above, in the case where the protection film 14 has the multilayer structure, the silicon nitride film of the first layer 14a enhances withstand voltage by an electric field moderation effect. In addition, the second layer 14b suppresses deformation of the diaphragm 11b.

In particular, since the first layer 14a is made of the silicon nitride as a main component, the first layer 14a generally exerts a tensile stress against a silicon substrate when applied with heat. Therefore, as compared with a structure without having the protection film 14, the first layer 14a acts to suppress deformation of the diaphragm 11b. On the other hand, the silicon oxide film of the second layer 14b exerts a compressive stress against a silicon substrate. That is, the second layer 14b acts to cancel the tensile stress of the first layer 14a. Therefore, the diaphragm 11 is less likely affected, and deformation of the diaphragm 11 can be reduced.

In the present embodiment, as the multilayer protection film 14, the first layer 14a is exemplarily provided by a silicon nitride, and the second layer 14b is exemplarily provided by a silicon oxide film. However, the combination of the first layer 14a and the second layer 14b is not limited to the above combination of the insulation film and a conductive film, and may be arbitrary. For example, the first layer 14a may be provided by a TEOS film, and the second layer 14b may be provided by an aluminum film.

However, in order to achieve the electric field moderation effect between the protection film 14 and the oxide film 13, the first layer 14a is preferably provided by the silicon nitride film. In order to smoothly exchange electric charges between the flow of plasma and the protection film 14, the second layer 14b, which is directly exposed to the flow of plasma, is preferably provided by an electrically conductive film.

The multilayer structure of the protection film 14 is not limited to the two layer structure, but may be a layer structure having three or more layers. Further, each of the layers of the protection film 14 may be formed in any way that is suitable to each of the layers. For example, the silicon nitride film of the first layer 14a may be formed of a CVD technique, and the silicon oxide film of the second layer 14b may be made by a sputtering technique.

### Other Embodiments

In the embodiments described above, the semiconductor devices 100 and 110 are exemplarily pressure sensors. However, the application of the present disclosure is not limited to the pressure sensor, and may be applied to any devices in which a first substrate 11 having an oxide film 13 as an anti-out diffusion film and a second substrate 12, which is a separate substrate from the first substrate 11, are bonded to each other by means of the atmospheric pressure plasma so that it can achieve the effects of the protection film 14.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A semiconductor device comprising:
a first substrate having a first surface;
a second substrate having a second surface, a part of the second surface being bonded to a part of the first surface of the first substrate with atmospheric pressure plasma activation;
an oxide film disposed on the first surface of the first substrate; and
a protection film layered on a surface of the oxide film opposite to the first substrate.

2. The semiconductor device according to claim 1, wherein
the protection film is an insulation film.

3. The semiconductor device according to claim 2, wherein
the protection film includes a silicon nitride film.

4. The semiconductor device according to claim 3, wherein
the protection film has a multilayer structure including a silicon oxide film and the silicon nitride film.

5. The semiconductor device according to claim 1, wherein
the protection film is an electrically conductive film.

6. The semiconductor device according to claim 1, wherein
the protection film is a polysilicon film.

7. A method for manufacturing a semiconductor device that includes a first substrate having a first surface and a second substrate having a second surface a part of which is bonded to a part of the first surface of the first substrate with atmospheric pressure plasma activation, the method comprising:
preparing the first substrate;
forming an oxide film on the first surface of the first substrate;
forming an impurity region in the first substrate;
forming a protection film on a surface of the oxide film opposite to the first substrate, after the forming of the oxide film and the forming of the impurity region;
performing a plasma activation treatment to the first surface at an atmospheric pressure, after the forming of the protection film;
joining the first surface of the first substrate and the second surface of the second substrate, after the performing of the plasma activation treatment; and
performing a heat treatment to the first substrate and the second substrate so as to bond the part of the first surface and the part of the second surface to each other, after the joining of the first surface and the second surface.

8. The method for manufacturing the semiconductor device according to claim 7, wherein
the protection film is an insulation film.

9. The method for manufacturing the semiconductor device according to claim 8, wherein
the protection film includes a silicon nitride film.

10. The method for manufacturing the semiconductor device according to claim 9, wherein
the protection film has a multilayer structure including a silicon oxide film and the silicon nitride film layered on one another.

11. The method for manufacturing the semiconductor device according to claim 7, wherein
the protection film is an electrically conductive film.

12. The method for manufacturing the semiconductor device according to claim 11, wherein
the protection film is a polysilicon film.
